(19) United States
(12) Patent Application Publication
(10) Pub. No.: US 2024/0264990 A1
(43) Pub. Date: Aug. 8, 2024

(54) LARGE DATA OBJECT TRANSFER AND STORAGE FOR MICROSERVICES

(71) Applicant: Dell Products L.P., Round Rock, TX (US)

(72) Inventor: Anshul Kumar, Waterloo, TX (US)

(73) Assignee: Dell Products L.P., Round Rock, TX (US)

(21) Appl. No.: 18/165,404

(22) Filed: Feb. 7, 2023

(51) Int. Cl. G06F 16/22; G06F 16/25; H03M 7/30

(52) U.S. Cl. CPC G06F 16/2219; G06F 16/258; H03M 7/3084

(57) ABSTRACT

In one aspect, an example methodology implementing the disclosed techniques includes, by a computing device, receiving a request to write a first data object to an object database. The method also includes, responsive to a determination that the first data object is a large data object, by the computing device, serializing the first data object, compressing the serialized first data object into a format that can be stored in the object database, and saving the compressed serialized first data object within the object database. The method may further include, by the computing device, extracting one or more fields which are queryable from the first data object and saving the one or more queryable fields with the compressed serialized first data object within the object database.

### BACKGROUND

Use of cloud native and microservices technologies are becoming more common. Cloud native computing is software development approach that utilizes cloud computing to create scalable applications within dynamic environments such as cloud or cloud-like computing environments. Common in cloud native computing architectures are microservices. A microservice (e.g., a microservice architecture) is an architecture that structures an application as a collection of separate, loosely coupled services, which are independently deployable.

Database systems generally provide the ability to store and retrieve various types of data, including large data objects, from various databases. It has become increasingly more common with the adoption of cloud native and microservice technologies for systems working on large data objects to observe exponential increase in data storage and network consumption. This increase in data storage and network consumption reduces performance when transferring large data objects between distributed components with tens or hundreds of microservices.

### SUMMARY

This Summary is provided to introduce a selection of concepts in simplified form that are further described below in the Detailed Description. This Summary is not intended to identify key or essential features or combinations of the claimed subject matter, nor is it intended to be used to limit the scope of the claimed subject matter.

In accordance with one illustrative embodiment provided to illustrate the broader concepts, systems, and techniques described herein, a method includes, by a computing device, receiving a request to write a first data object to an object database. The method also includes, responsive to a determination that the first data object is a large data object, by the computing device, serializing the first data object, compressing the serialized first data object into a format that can be stored in the object database, and saving the compressed serialized first data object within the object database.

In some embodiments, serializing the first data object includes using a binary serializer to convert the first data object to a byte array.

In some embodiments, compressing the serialized first data object includes using an LZ4 algorithm to compress the serialized first data object.

In some embodiments, compressing the serialized first data object includes using a Zstandard (ZSTD) algorithm to compress the serialized first data object.

In some embodiments, the method also includes, responsive to the determination that the first data object is a large data object, by the computing device, extracting one or more fields which are queryable from the first data object and saving the one or more queryable fields with the compressed serialized first data object within the object database.

In some embodiments, the method further includes, responsive to a determination that the first data object is not a large data object, saving, by the computing device, the first data object within the object database.

In some embodiments, the method also includes, responsive to receiving a request to read a second data object from the object database, reading, by the computing device, the second data object from the object database. The method further includes, responsive to a determination that the second data object read from the object database is a compressed byte array, by the computing device, deserializing the second data object into a POCO entity which includes the compressed byte array, wherein the compressed byte array represents the second data object and sending the compressed byte array in a response to the request to read the second data object.

In some embodiments, the method further includes, responsive to a determination that the second data object read from the object database is not a compressed byte array, by the computing device, by the computing device, deserializing the second data object into a POCO entity, serializing the POCO entity into a JSON object, and sending the JSON object in a response to the request to read the second data object. In one aspect, the method also includes, by the computing device, prior to sending the JSON object, compressing the JSON object and sending the compressed JSON object in the response to the request to read the second data object.

According to another illustrative embodiment provided to illustrate the broader concepts described herein, a system includes one or more non-transitory machine-readable mediums configured to store instructions and one or more processors configured to execute the instructions stored on the one or more non-transitory machine-readable mediums. Execution of the instructions causes the one or more processors to carry out a process corresponding to the aforementioned method or any described embodiment thereof.

According to another illustrative embodiment provided to illustrate the broader concepts described herein, a non-transitory machine-readable medium encodes instructions that when executed by one or more processors cause a process to be carried out, the process corresponding to the aforementioned method or any described embodiment thereof.

It should be appreciated that individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the claims appended hereto.

### BRIEF DESCRIPTION OF THE DRAWINGS

The foregoing and other objects, features and advantages will be apparent from the following more particular description of the embodiments, as illustrated in the accompanying drawings in which like reference characters refer to the same parts throughout the different views. The drawings are not necessarily to scale, emphasis instead being placed upon illustrating the principles of the embodiments.

FIG. 1 is a diagram illustrating an example network environment of computing devices in which various aspects of the disclosure may be implemented, in accordance with an embodiment of the present disclosure.

FIG. 2 is a block diagram illustrating selective components of an example computing device in which various aspects of the disclosure may be implemented, in accordance with an embodiment of the present disclosure.

FIG. 3 is a diagram of a cloud computing environment in which various aspects of the concepts described herein may be implemented.

FIG. 4 is a block diagram of an illustrative system for large data object transfer and storage, in accordance with an embodiment of the present disclosure.

FIG. 5 is a flow diagram of an example process for writing a large data object, in accordance with an embodiment of the present disclosure.

FIG. 6 is a flow diagram of an example process for reading a large data object, in accordance with an embodiment of the present disclosure.

### DETAILED DESCRIPTION

When systems, e.g., a resource provider (e.g., a server application) and a resource consumer (e.g., a client application), are working with large data objects (e.g., data objects of sizes 100 kilobytes (kb) or larger), there are numerous problems which lead to slow or reduced data object transfer throughput and/or performance. The reduced throughput and/or performance during transfer (e.g., storage and retrieval) of large data objects is primarily caused by several challenges including increased network latency, database cache memory (e.g., working set) consumption, and increased serialization and deserialization times between the client application and the server application.

Network latency increases when transferring large data objects (e.g., large documents) to/from a non-relational database (e.g., a document database) since network latency is directly proportional to the size of the payload. In a document database, the cache memory (e.g., working set) allocated to a database process is consumed by a small number of large documents in a collection, which results in most of the read/write operations requiring input/output (IO) operations to disk. Also, when a large document is read by the server application, the time needed to deserialize the large document from the document database into the resource model (e.g., a plain old class object (POCO) or object class entity) increases and, in some cases significantly increases due to the large size of the document. There will also be increased network latency in sending the resource model to the client application (e.g., in response to a client request for the document) due to the large size of the document. Finally, at the client, the time needed to deserialize the received resource model (e.g., the received server response) to an object increases due to the large size of the document. Unfortunately, conventional techniques for transferring large data objects between distributed components in such architectures are typically inefficient in addressing the challenges noted above.

Certain embodiments of the concepts, techniques, and structures disclosed herein generally relate to systems and methods for comprehensive, end-to-end optimization in exchanging large data objects. The various disclosed embodiments significantly improve end-to-end network latency, memory footprint, and storage size for systems that work with large data objects. This can be achieved by, according to some embodiments, a server application of a non-relational database serializing (e.g., binary serializing) a large data object which is to be written to (e.g., saved in) the database into a byte array. The server application can then compress the byte array and save the compressed byte array, which represents the large data object, within the database. For example, the compressed byte array may be saved as a database entity within the database instead of the actual large data object. The database entity associated with the saved compressed byte array is assigned an identifier (ID) which can be used to access the database entity. Compressing the data object at the application layer (e.g., by the server application) provides reduced network latency when writing to the database due to the smaller size of the compressed byte array as compared to the size of the large data object. Compressing the data object at the application layer also reduces the storage footprint of the data object, thus increasing the number of data objects that can be maintained in the database cache memory. That is to say, since the storage footprint of the compressed byte array which represents the data object is reduced at the application layer, the number of compressed byte arrays which represent data objects that can be maintained in cache memory is increased.

In some embodiments, the server application can extract one or more fields which are queryable from the large data object. The extracted fields may be used in an index for querying the data object. The server application can save the extracted fields along with the compressed byte array within the database (e.g., assign to the extracted fields the ID which was assigned to the compressed byte array).

In a read transaction, in response to a request to read a data object from a client application, for instance, the server application can read the requested data object from the database using an ID (e.g., the ID assigned to the database entity associated with the data object). Less time is needed to read the data object in its compressed form (e.g., read the data object as a compressed byte array) from the database due to the reduction in size provided by the compression. The server application deserializes the read data object into a POCO entity which includes the ID and the compressed byte array. Less time is needed to deserialize the data object from the database since the large data object is read from the database as a compressed byte array into the database entity object. Note that the server application does not serialize and decompress the data object read from the database. Also, less time is needed to send the byte array to the client application, thus resulting in reduced network latency. The server application can then send the compressed byte array to the client application in response to the client request. Note also that less time is needed to send the compressed byte array to the client application, thus resulting in reduced network latency. At the client, the client application can decompress and deserialize the compressed byte array received from the server application.

In the description that follows, although certain embodiments and/or examples are described in the context of large data object transfers and non-relational database systems, it will be appreciated in light of this disclosure that such embodiments and/or examples are not restricted as such. For example, the concepts, techniques, and structures disclosed herein are applicable to message streams (e.g., KAFKA) and publishing/consuming large objects from the message streams.

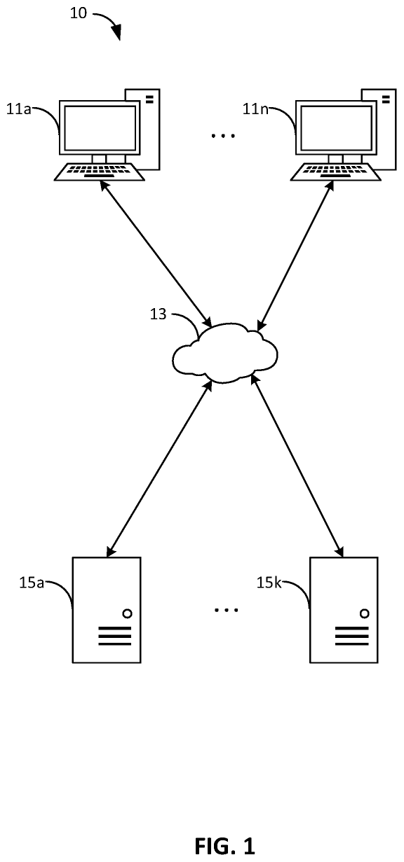

Referring now to FIG. 1, shown is a diagram illustrating an example network environment 10 of computing devices in which various aspects of the disclosure may be implemented, in accordance with an embodiment of the present disclosure. As shown, environment 10 includes one or more client machines 11a-11n (11 generally), one or more server machines 15a-15k (15 generally), and one or more networks 13. Client machines 11 can communicate with server machines 15 via networks 13. Generally, in accordance with client-server principles, a client machine 11 requests, via network 13, that a server machine 15 perform a computation or other function, and server machine 15 responsively fulfills the request, optionally returning a result or status indicator in a response to client machine 11 via network 13.

In some embodiments, client machines 11 can communicate with remote machines 15 via one or more intermediary appliances (not shown). The intermediary appliances may be positioned within network 13 or between networks 13. An intermediary appliance may be referred to as a network interface or gateway. In some implementations, the intermediary appliance may operate as an application delivery controller (ADC) in a datacenter to provide client machines (e.g., client machines 11) with access to business applications and other data deployed in the datacenter. The intermediary appliance may provide client machines with access to applications and other data deployed in a cloud computing environment, or delivered as Software as a Service (SaaS) across a range of client devices, and/or provide other functionality such as load balancing, etc.

Client machines 11 may be generally referred to as computing devices 11, client devices 11, client computers 11, clients 11, client nodes 11, endpoints 11, or endpoint nodes 11. Client machines 11 can include, for example, desktop computing devices, laptop computing devices, tablet computing devices, mobile computing devices, workstations, and/or hand-held computing devices. Server machines 15 may also be generally referred to a server farm 15. In some embodiments, a client machine 11 may have the capacity to function as both a client seeking access to resources provided by server machine 15 and as a server machine 15 providing access to hosted resources for other client machines 11.

Server machine 15 may be any server type such as, for example, a file server, an application server, a web server, a proxy server, a virtualization server, a deployment server, a Secure Sockets Layer Virtual Private Network (SSL VPN) server; an active directory server; a cloud server; or a server executing an application acceleration program that provides firewall functionality, application functionality, or load balancing functionality. Server machine 15 may execute, operate, or otherwise provide one or more applications. Non-limiting examples of applications that can be provided include software, a program, executable instructions, a virtual machine, a hypervisor, a web browser, a web-based client, a client-server application, a thin-client, a streaming application, a communication application, or any other set of executable instructions.

In some embodiments, server machine 15 may execute a virtual machine providing, to a user of client machine 11, access to a computing environment. In such embodiments, client machine 11 may be a virtual machine. The virtual machine may be managed by, for example, a hypervisor, a virtual machine manager (VMM), or any other hardware virtualization technique implemented within server machine 15.

Networks 13 may be configured in any combination of wired and wireless networks. Network 13 can be one or more of a local-area network (LAN), a wide area network (WAN), a metropolitan area network (MAN), a virtual private network (VPN), a primary public network, a primary private network, the Internet, or any other type of data network. In some embodiments, at least a portion of the functionality associated with network 13 can be provided by a cellular data network and/or mobile communication network to facilitate communication among mobile devices. For short range communications within a wireless local-area network (WLAN), the protocols may include 802.11, Bluetooth, and Near Field Communication (NFC).

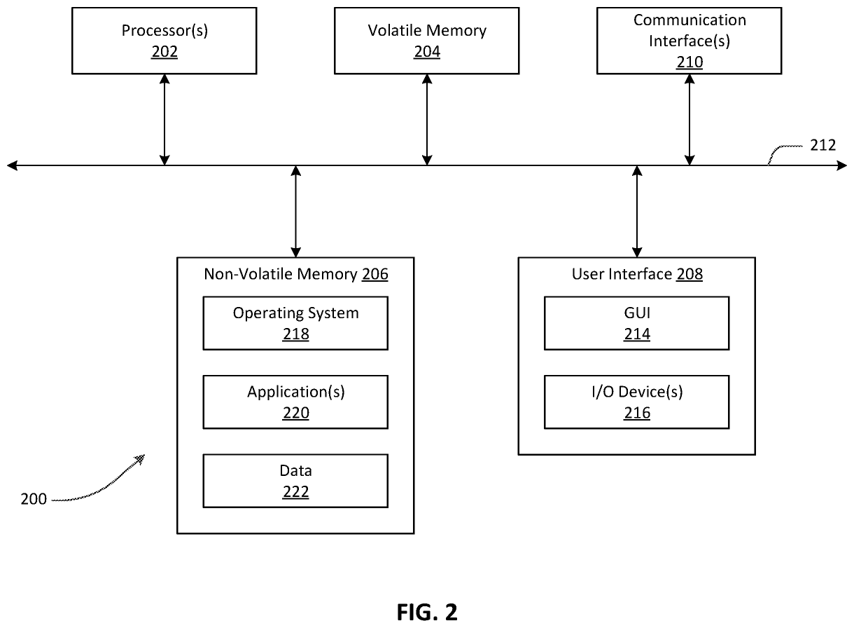

FIG. 2 is a block diagram illustrating selective components of an example computing device 200 in which various aspects of the disclosure may be implemented, in accordance with an embodiment of the present disclosure. For instance, client machines 11 and/or server machines 15 of FIG. 1 can be substantially similar to computing device 200. As shown, computing device 200 includes one or more processors 202, a volatile memory 204 (e.g., random access memory (RAM)), a non-volatile memory 206, a user interface (UI) 208, one or more communications interfaces 210, and a communications bus 212.

Non-volatile memory 206 may include: one or more hard disk drives (HDDs) or other magnetic or optical storage media; one or more solid state drives (SSDs), such as a flash drive or other solid-state storage media; one or more hybrid magnetic and solid-state drives; and/or one or more virtual storage volumes, such as a cloud storage, or a combination of such physical storage volumes and virtual storage volumes or arrays thereof.

User interface 208 may include a graphical user interface (GUI) 214 (e.g., a touchscreen, a display, etc.) and one or more input/output (I/O) devices 216 (e.g., a mouse, a keyboard, a microphone, one or more speakers, one or more cameras, one or more biometric scanners, one or more environmental sensors, and one or more accelerometers, etc.).

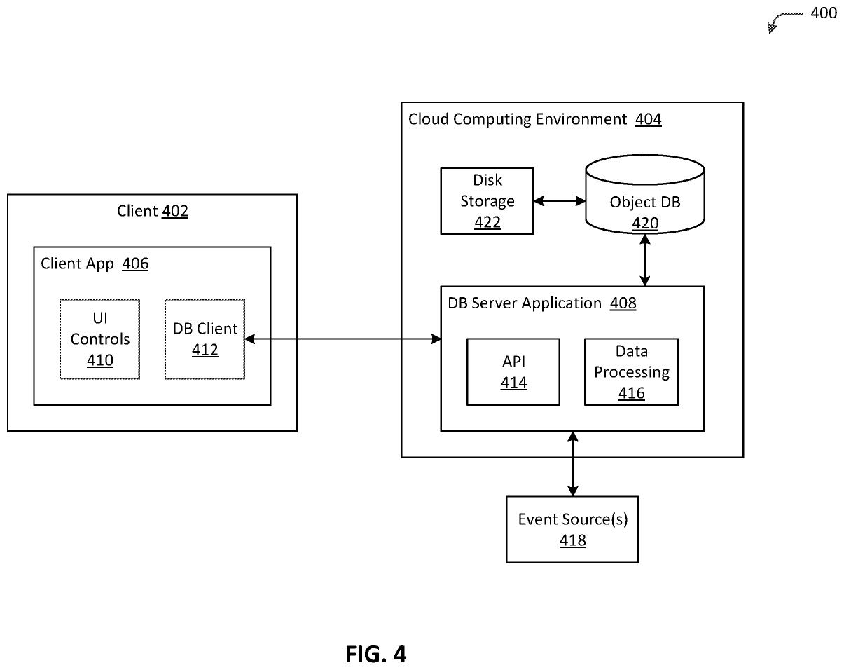

Non-volatile memory 206 stores an operating system 218, one or more applications 220, and data 222 such that, for example, computer instructions of operating system 218 and/or applications 220 are executed by processor(s) 202 out of volatile memory 204. In one example, computer instructions of operating system 218 and/or applications 220 are executed by processor(s) 202 out of volatile memory 204 to perform all or part of the processes described herein (e.g., processes illustrated and described with reference to FIGS. 4 through 6). In some embodiments, volatile memory 204 may include one or more types of RAM and/or a cache memory that may offer a faster response time than a main memory. Data may be entered using an input device of GUI 214 or received from I/O device(s) 216. Various elements of computing device 200 may communicate via communications bus 212.

The illustrated computing device 200 is shown merely as an illustrative client device or server and may be implemented by any computing or processing environment with any type of machine or set of machines that may have suitable hardware and/or software capable of operating as described herein.

Processor(s) 202 may be implemented by one or more programmable processors to execute one or more executable instructions, such as a computer program, to perform the functions of the system. As used herein, the term “processor” describes circuitry that performs a function, an operation, or a sequence of operations. The function, operation, or sequence of operations may be hard coded into the circuitry or soft coded by way of instructions held in a memory device and executed by the circuitry. A processor may perform the function, operation, or sequence of operations using digital values and/or using analog signals.

In some embodiments, the processor can be embodied in one or more application specific integrated circuits (ASICs), microprocessors, digital signal processors (DSPs), graphics processing units (GPUs), microcontrollers, field programmable gate arrays (FPGAs), programmable logic arrays (PLAs), multi-core processors, or general-purpose computers with associated memory.

Processor 202 may be analog, digital or mixed signal. In some embodiments, processor 202 may be one or more physical processors, or one or more virtual (e.g., remotely located or cloud computing environment) processors. A processor including multiple processor cores and/or multiple processors may provide functionality for parallel, simultaneous execution of instructions or for parallel, simultaneous execution of one instruction on more than one piece of data.

Communications interfaces 210 may include one or more interfaces to enable computing device 200 to access a computer network such as a Local Area Network (LAN), a Wide Area Network (WAN), a Personal Area Network (PAN), or the Internet through a variety of wired and/or wireless connections, including cellular connections.

In described embodiments, computing device 200 may execute an application on behalf of a user of a client device. For example, computing device 200 may execute one or more virtual machines managed by a hypervisor. Each virtual machine may provide an execution session within which applications execute on behalf of a user or a client device, such as a hosted desktop session. Computing device 200 may also execute a terminal services session to provide a hosted desktop environment. Computing device 200 may provide access to a remote computing environment including one or more applications, one or more desktop applications, and one or more desktop sessions in which one or more applications may execute.

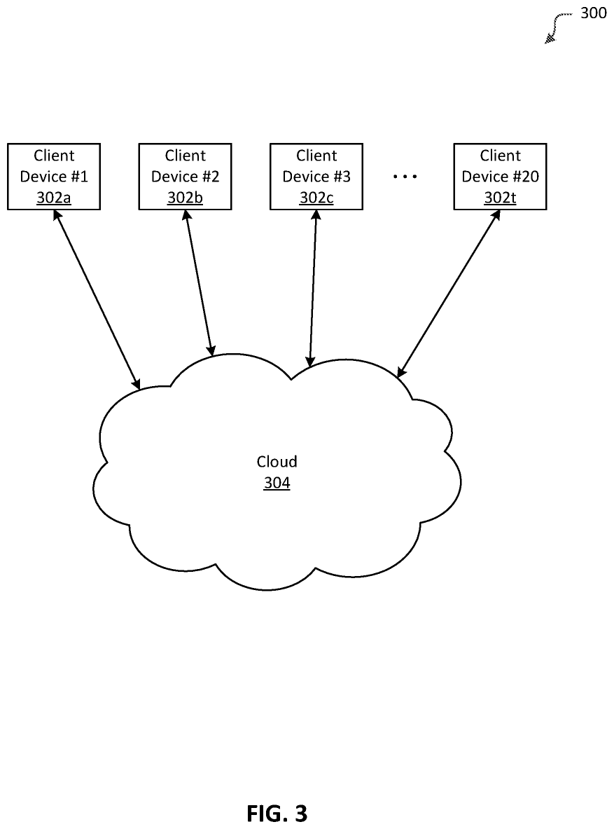

Referring to FIG. 3, shown is a diagram of a cloud computing environment 300 in which various aspects of the concepts described herein may be implemented. Cloud computing environment 300, which may also be referred to as a cloud environment, cloud computing, or cloud network, can provide the delivery of shared computing resources and/or services to one or more users or tenants. For example, the shared resources and services can include, but are not limited to, networks, network bandwidth, servers, processing, memory, storage, applications, virtual machines, databases, software, hardware, analytics, and intelligence.

In cloud computing environment 300, one or more client devices 302a-302t (such as client machines 11 and/or computing device 200 described above) may be in communication with a cloud network 304 (sometimes referred to herein more simply as a cloud 304). Cloud 304 may include back-end platforms such as, for example, servers, storage, server farms, or data centers. The users of clients 302a-302t can correspond to a single organization/tenant or multiple organizations/tenants. More particularly, in one implementation, cloud computing environment 300 may provide a private cloud serving a single organization (e.g., enterprise cloud). In other implementations, cloud computing environment 300 may provide a community or public cloud serving one or more organizations/tenants.

In some embodiments, one or more gateway appliances and/or services may be utilized to provide access to cloud computing resources and virtual sessions. For example, a gateway, implemented in hardware and/or software, may be deployed (e.g., reside) on-premises or on public clouds to provide users with secure access and single sign-on to virtual, SaaS, and web applications. As another example, a secure gateway may be deployed to protect users from web threats.

In some embodiments, cloud computing environment 300 may provide a hybrid cloud that is a combination of a public cloud and a private cloud. Public clouds may include public servers that are maintained by third parties to client devices 302a-302t or the enterprise/tenant. The servers may be located off-site in remote geographical locations or otherwise.

Cloud computing environment 300 can provide resource pooling to serve clients devices 302a-302t (e.g., users of client devices 302a-302n) through a multi-tenant environment or multi-tenant model with different physical and virtual resources dynamically assigned and reassigned responsive to different demands within the respective environment. The multi-tenant environment can include a system or architecture that can provide a single instance of software, an application, or a software application to serve multiple users. In some embodiments, cloud computing environment 300 can include or provide monitoring services to monitor, control, and/or generate reports corresponding to the provided shared resources and/or services.

In some embodiments, cloud computing environment 300 may provide cloud-based delivery of various types of cloud computing services, such as Software as a Service (SaaS), Platform as a Service (PaaS), Infrastructure as a Service (IaaS), and/or Desktop as a Service (DaaS), for example. IaaS may refer to a user renting the use of infrastructure resources that are needed during a specified time period. IaaS providers may offer storage, networking, servers, or virtualization resources from large pools, allowing the users to quickly scale up by accessing more resources as needed. PaaS providers may offer functionality provided by IaaS, including, e.g., storage, networking, servers, or virtualization, as well as additional resources such as, for example, operating systems, middleware, and/or runtime resources. SaaS providers may offer the resources that PaaS provides, including storage, networking, servers, virtualization, operating systems, middleware, or runtime resources. SaaS providers may also offer additional resources such as, for example, data and application resources. DaaS (also known as hosted desktop services) is a form of virtual desktop service in which virtual desktop sessions are typically delivered as a cloud service along with the applications used on the virtual desktop.

FIG. 4 is a block diagram of an illustrative system 400 for large data object transfer and storage, in accordance with an embodiment of the present disclosure. Illustrative system 400 includes a client application 406 operable to run on a client 402 and configured to communicate with a cloud computing environment 404 via one or more computer networks. Client 402 and cloud computing environment 404 of FIG. 4 can be the same as or similar to client 11 of FIG. 1 and cloud computing environment 300 of FIG. 3, respectively.

As shown in FIG. 4, a database server application 408 can be provided within cloud computing environment 404. For example, in one implementation, database server application 408 can be provided as a service (e.g., a microservice) within cloud computing environment 404. Client application 406 and database server application 408 can interoperate to provide optimized large data object transfer and storage, as variously disclosed herein. To promote clarity in the drawings, FIG. 4 shows a single client application 406 communicably coupled to database server application 408. However, embodiments of database server application 408 can be used to service many client applications (e.g., client applications 406) running on client devices (e.g., clients 402) associated with one or more organizations and/or users. Client application 406 and/or database server application 408 may be implemented as computer instructions executable to perform the corresponding functions disclosed herein. Client application 406 and product analysis service 408 can be logically and/or physically organized into one or more components. In the example of FIG. 4, client application 406 includes UI controls 410 and a database (DB) client 412. Also, in this example, database server application 408 includes an application programming interface (API) module 414 and a data processing module 416.

The client-side client application 406 can communicate with the cloud-side database server application 408 using an API. For example, client application 406 can utilize DB client 412 to send requests (or “messages”) to database server application 408 wherein the requests are received and processed by API module. Likewise, database server application 408 can utilize API module 414 to send responses/messages to client application 406 wherein the responses/messages are received and processed by DB client 412.

Referring to database server application 408, data processing module 416 is operable to perform operations to write to an object database 420. Object database 420 can be provided as any type of database (e.g., a document-oriented database) that represents data or information in the form of objects as opposed to relational databases which organize data into one or more tables. Data processing module 416 can perform a write process to write a data object, such as, for example, a document, to object database 420. For example, data processing module 416 can perform the write process in response to database server application 408 receiving a request to write a data object to object database 420. The request, for example, may be from a client application (e.g., client application 406 on client 402). Additionally or alternatively, the request may be from an event source 418. Event sources 418 may correspond to various upstream applications that can send data (e.g., data objects) to database server application 408. The client applications and/or event sources 418 can utilize an API (e.g., API module 414) to send requests to database server application 408 to write data objects to object database 420.

Writing to object database 420 equates to manipulating data within object database 420. Writing allows data processing module 416 to modify the contents of object database 420. This can mean gathering and storing new data, updating existing information, or deleting, among other things. Thus, in some implementations, data processing module 416 can be understood as providing functionality which can be consumed by client applications (e.g., client application 406) and upstream applications (e.g., event sources 418) to transact (e.g., store or retrieve data, query and manipulate data, etc.) with object database 420.

In response to a request to write a data object to object database 420 being received, data processing module 416 can determine whether the data object to be written is a large data object. For example, a large data object can be defined as a data object that is at least a predetermined threshold size such as, for example, 100 kb. The predetermined threshold size can be configured as an organizational policy. If data processing module 416 determines that the data object is not a large data object, data processing module 416 can write (or “save”) the data object to object database 420, as conventionally done.

If data processing module 416 determines that the data object is a large data object, data processing module 416 can serialize the data object (i.e., the large data object) to convert (or “marshal” or “marshaling”) the data object into a format such as a byte array. In some embodiments, data processing module 416 can utilize a binary serializer, such as MessagePack which provides an efficient binary serialization format, to convert the data object to a byte array (e.g., a stream of bytes). Data processing module 416 can then compress the byte array (e.g., compress the serialized large data object). In some embodiments, data processing module 416 can utilize a data compression algorithm, such as LZ4 or Zstandard (ZSTD), to compress the byte array.

Data processing module 416 can save the compressed byte array which represents the large data object within object database 420. That is, the compressed serialized large data object is saved within object database 420 instead of the actual large data object. Within object database 420, the database entity associated with the saved compressed byte array is assigned an identifier (ID) which can be used to access the database entity. Writing the compressed byte array in object database 420 is fast and efficient (e.g., reduced network latency) due to the reduced size of the compressed byte array in comparison to the size of the actual large data object. Also, storage consumption in object database 420 is reduced due to the reduced size of the compressed byte array. As a result, an increased number of data objects can be maintained in the cache memory of object database 420 which, in turn, reduces and, in some cases greatly reduces and ideally eliminates, the need to perform IO operations to a storage tier (e.g., a disk storage 422) to write/read data objects.

In some embodiments, data processing module 416 can extract one or more fields which are queryable from the data object. The extracted fields may be used in an index for querying the data object (e.g., an index for querying the large data object) even though the compressed byte array which represents the data object is saved within object database 420. For example, suppose the large data object is a patient medical record. In this example, data processing module 416 may extract from the large data object fields such as, for example, patient's name, address, phone number, and other information related to the patient which are queryable. Data processing module 416 can then save the extracted fields (i.e., queryable fields) within object database 420 along with the compressed byte array which represents the large data object. As a result, the saved queryable fields can be identified using the ID assigned to the database entity associated with the compressed byte array, and available for being queried, for example by a client application.

Data processing module 416 is also operable to perform operations to read from object database 420. Data processing module 416 can perform a read process to read a data object, such as, for example, a document, from object database 420. For example, data processing module 416 can perform the read process in response to database server application 408 receiving a request to read a data object from object database 420. The request, for example, may be from a client application (e.g., client application 406 on client 402) and include an ID of a database entity in object database 420 (i.e., ID of a database entity associated with the data object).

In response to a request to read a data object from object database 420 being received, data processing module 416 can use the ID included or otherwise provided with the request to read a data object from object database 420. Data processing module 416 can then determine whether the read data object is a compressed byte array. In other words, data processing module 416 can determine whether the read data object is a large data object. If data processing module 416 determines that the read data object is not a compressed byte array, data processing module 416 can send the data object read from object database 420 in a response to the request to read the data object, as conventionally done. For example, data processing module 416 can deserialize the data object read from object database 420 into a POCO entity and serialize the POCO entity into, for instance, a JavaScript Object Notation (JSON) object. In some cases, data processing module 416 may compress the JSON object, for example, if compression is specified in the request to read the data object (e.g., if compression is specified in the request header). Data processing module 414 can then sent the JSON object (or the compressed JSON object) in a response to the request to read the data object.

If data processing module 416 determines that the read data object is a compressed byte array, data processing module 416 can deserialize the data object read from object database 420 into a POCO entity which includes the ID and the compressed byte array. In some embodiments, data processing module 416 can utilize the binary serializer to deserialize the read data object. Reading the large data object from object database 420 is fast and efficient (e.g., reduced network latency) since it is read from object database 420 as a compressed byte array which represents the large data object, and the compressed byte array is smaller in size than the actual large data object. Also, deserialization is magnitudes faster since the smaller byte array representing the large data object is read from object database 420 and deserialized instead of the actual large data object.

Data processing module 416 can then extract the compressed byte array from the POCO entity and send the compressed byte array in a response to the request to read the data object. For example, assuming that the request is received from a client application (e.g., client application 406), data processing module 416 can send the compressed byte array in a response to the client application. Sending the compressed byte array to the client application is fast and efficient (e.g., reduced network latency) due to the reduced size of the compressed byte array in comparison to the size of the actual large data object. Additionally, data processing module 416 does not serialize and decompress the compressed byte array again into a different content type prior to sending the compressed byte array to the client application, which reduces processing time at data processing module 416 (e.g., increases the efficiency of data processing module 416).

At the client, the compressed byte array received from database server application 408 can be decompressed and deserialized. For example, a client application can use a data compression algorithm, such as LZ4 or ZSTD, to decompress the compressed byte array, and a binary serializer, such as MessagePack, to deserialize the decompressed byte array into an object (e.g., reconstruct the data object from the decompressed byte array). In some embodiments, the type of compression (e.g., LZ4) and data (e.g., MessagePack) may be indicated in the response to the request sent by database server application 408. The client application can then determine the algorithms to use to decompress and deserialize the received byte array from the type of compression and data indicated in the response. For example, in the case of a Hypertext Transfer Protocol (HTTP) message, the type of compression and data may be indicated in the “content-encoding” and “content-type” headers, respectfully. In some embodiments, the client application can specify the type of compression and data that is to be used by data processing module 416 in the request to read a data object sent to database server application 408. In some embodiments, the client application may negotiate with database server application 408 (e.g., data processing module 416) the type of compression and data that is to be used by data processing module 416.

Referring to client application 406, client application 406 can include various UI controls 410 that enable a user (e.g., a user of client 402) to access and interact with database server application 408. For example, UI controls 410 can include UI elements/controls, such as input fields and text fields, that a user can use to enter (e.g., specify) a data object (e.g., an ID of a data object) that is to be read from object database 420. UI controls 410 can include UI elements/controls that a user can click/tap to request reading of the specified data object from object database 420. In response to the user's input, client application 406 can send a message to database server application 408 requesting that the specified data object be read from object database 420.

In the embodiment of FIG. 4, client application 406 is shown as a stand-alone client application. In other embodiments, client application 406 may be implemented as or include a web browser for accessing web-based applications (e.g., SaaS applications) along with other types of web apps and websites. In such embodiments, UI controls 410 may be provided by one or more web pages, such as product web pages or other web pages providing access to data, being accessed using the web browser. By way of an example, the user may use the web browser to request a product web page from a particular website. In this example, the product web page may include UI controls 410 (e.g., links) that the user can click/tap to request information/details/data/etc. about various products listed in the product web page. In response to the user clicking/tapping a link, a request can be sent to database server application 408 to read the data object associated with the clicked/tapped link from object database 420.

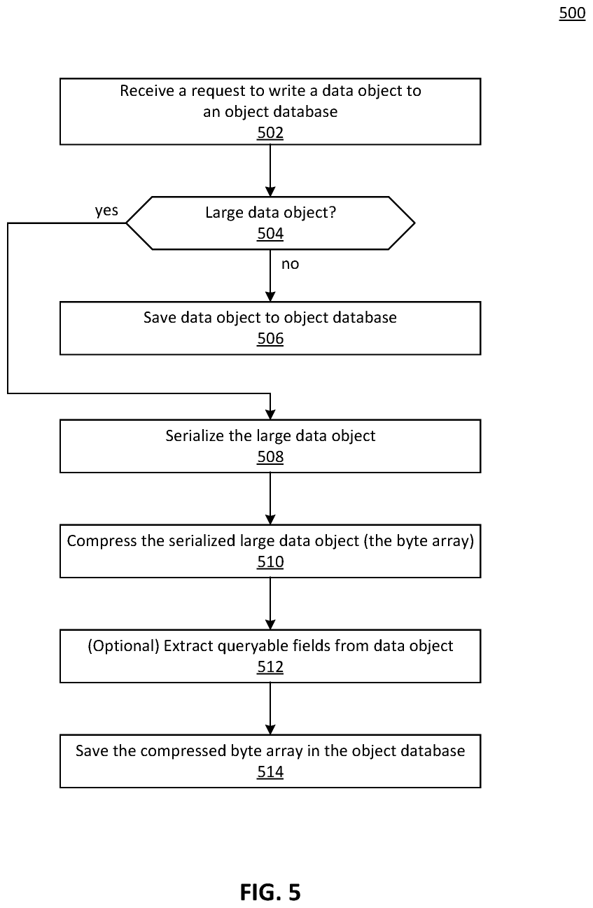

FIG. 5 is a flow diagram of an example process 500 for writing a large data object, in accordance with an embodiment of the present disclosure. Illustrative process 500 may be implemented, for example, within database server application 408 of FIG. 4 and executed in response to database server application 408 receiving a request to write a data object to object database 420.

With reference to process 500 of FIG. 5, at 502, a request to write a data object to an object database may be received. The request may be received, for example, from a client application (e.g., client application 406 of FIG. 4) or an upstream application (e.g., event source 418 of FIG. 4).

At 504, a check may be performed to determine whether the data object to write to the object database is a large data object. For example, in one implementation, the size of the data object may be checked against a predetermined threshold size (e.g., 100 kb) to determine whether the data object is a large data object.

If, at 504, a determination is made that the data object to write to the object database is not a large data object, then, at 506, the data object may be saved to the object database as conventionally done. For example, the data object may be saved as a database entity within the object database.

Otherwise, if, at 504, a determination is made that the data object to write to the database is a large data object, then, at 508, the data object (i.e., the large data object) may be serialized to convert the data object to a format, such as a byte array, which is suitable for storing in the object database. For example, in one implementation, a binary serializer, such as MessagePack, can be used to serialize the data object to a byte array.

At 510, the serialized data object (e.g., the byte array) may be compressed. For example, in one implementation, the byte array, which represents the data object, can be compressed using the LZ4 or other suitable lossless compression algorithm. The resulting compressed byte array represents the large data object.

At 512, one or more fields which are queryable may optionally be extracted from the data object. The extracted fields may be used, for example, by a client application for querying the data object.

At 514, the compressed byte array may be saved within the object database. For example, the compressed byte array may be saved as a database entity within the object database. In cases where queryable fields are extracted from the data object at 512, the queryable fields may be saved along with the compressed byte array within the object database.

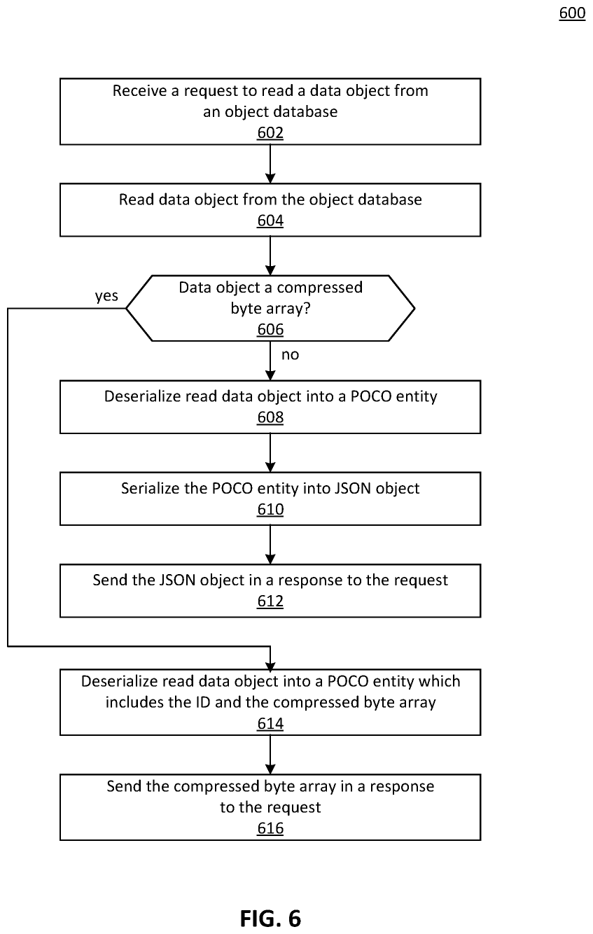

FIG. 6 is a flow diagram of an example process 600 for reading a large data object, in accordance with an embodiment of the present disclosure. Illustrative process 600 may be implemented, for example, within database server application 408 of FIG. 4 and executed in response to database server application 408 receiving a request to read a data object from object database 420.

With reference to process 600 of FIG. 6, at 602, a request to read a data object from an object database may be received. The request can include a unique ID of a database entity within the object database that is associated with the data object. The request may be received, for example, from a client application (e.g., client application 406 of FIG. 4).

At 604, the requested data object may be read from the object database. For example, the database entity associated with the data object can be read using the unique ID included with the request.

At 606, a check may be performed to determine whether the data object read from the object database is a compressed byte array. That is, a check may be performed to determine whether the data object read from the object database is a large data object.

If, at 606, a determination is made that the data object read from the object database is not a compressed byte array, then, at 608, the data object may be deserialized into a POCO entity. At 610, the deserialized data object (e.g., the POCO entity) may be serialized into a JSON object. In some cases, such as, for example, when compression is specified in the request, the JSON object may be compressed using a suitable compression algorithm. At 612, the JSON object (or the compressed JSON object) may be sent in a response to the request. For example, the JSON object can be sent in a response to the client application that sent the request.

Otherwise, if, at 606, a determination is made that the data object read from the object database is a compressed byte array, then, at 614, the data object read from the object database may be deserialized. For example, in one implementation, a binary serializer, such as MessagePack, can be used to deserialize the data object into a POCO entity which includes the ID and the compressed byte array.

At 616, the compressed byte array from the POCO entity may be sent in a response to the request. Note that the compressed byte array sent in the response represents the requested large data object. The compressed byte array in the response may be decompressed and deserialized by the client (e.g., client application) to recreate the large data object.

In the foregoing detailed description, various features of embodiments are grouped together for the purpose of streamlining the disclosure. This method of disclosure is not to be interpreted as reflecting an intention that the claims require more features than are expressly recited. Rather, inventive aspects may lie in less than all features of each disclosed embodiment.

As will be further appreciated in light of this disclosure, with respect to the processes and methods disclosed herein, the functions performed in the processes and methods may be implemented in differing order. Additionally or alternatively, two or more operations may be performed at the same time or otherwise in an overlapping contemporaneous fashion. Furthermore, the outlined actions and operations are only provided as examples, and some of the actions and operations may be optional, combined into fewer actions and operations, or expanded into additional actions and operations without detracting from the essence of the disclosed embodiments.

Elements of different embodiments described herein may be combined to form other embodiments not specifically set forth above. Other embodiments not specifically described herein are also within the scope of the following claims.

Reference herein to “one embodiment” or “an embodiment” means that a particular feature, structure, or characteristic described in connection with the embodiment can be included in at least one embodiment of the claimed subject matter. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the words “exemplary” and “illustrative” are used herein to mean serving as an example, instance, or illustration. Any aspect or design described herein as “exemplary” or “illustrative” is not necessarily to be construed as preferred or advantageous over other aspects or designs. Rather, use of the words “exemplary” and “illustrative” is intended to present concepts in a concrete fashion.

In the description of the various embodiments, reference is made to the accompanying drawings identified above and which form a part hereof, and in which is shown by way of illustration various embodiments in which aspects of the concepts described herein may be practiced. It is to be understood that other embodiments may be utilized, and structural and functional modifications may be made without departing from the scope of the concepts described herein. It should thus be understood that various aspects of the concepts described herein may be implemented in embodiments other than those specifically described herein. It should also be appreciated that the concepts described herein are capable of being practiced or being carried out in ways which are different than those specifically described herein.

Terms used in the present disclosure and in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, such recitation should be interpreted to mean at least the recited number (e.g., the bare recitation of “two widgets,” without other modifiers, means at least two widgets, or two or more widgets). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

All examples and conditional language recited in the present disclosure are intended for pedagogical examples to aid the reader in understanding the present disclosure, and are to be construed as being without limitation to such specifically recited examples and conditions. Although illustrative embodiments of the present disclosure have been described in detail, various changes, substitutions, and alterations could be made hereto without departing from the scope of the present disclosure. Accordingly, it is intended that the scope of the present disclosure be limited not by this detailed description, but rather by the claims appended hereto.

What is claimed is:

1. A method comprising:
receiving, by a computing device, a request to write a first data object to an object database; and
responsive to a determination that the first data object is a large data object, by the computing device:
serializing the first data object;
compressing the serialized first data object into a format that can be stored in the object database; and
saving the compressed serialized first data object within the object database.

2. The method of claim 1, wherein the serializing the first data object includes using a binary serializer to convert the first data object to a byte array.

3. The method of claim 1, wherein the compressing the serialized first data object includes using an LZ4 algorithm to compress the serialized first data object.

4. The method of claim 1, wherein the compressing the serialized first data object includes using a Zstandard (ZSTD) algorithm to compress the serialized first data object.

5. The method of claim 1, further comprising, responsive to the determination that the first data object is a large data object, by the computing device:
extracting one or more fields which are queryable from the first data object; and
saving the one or more queryable fields with the compressed serialized first data object within the object database.

6. The method of claim 1, further comprising, responsive to a determination that the first data object is not a large data object, saving, by the computing device, the first data object within the object database.

7. The method of claim 1, further comprising:
responsive to receiving a request to read a second data object from the object database, reading, by the computing device, the second data object from the object database; and
responsive to a determination that the second data object read from the object database is a compressed byte array, by the computing device:
deserializing the second data object into a POCO entity which includes the compressed byte array, wherein the compressed byte array represents the second data object; and
sending the compressed byte array in a response to the request to read the second data object.

8. The method of claim 7, further comprising, responsive to a determination that the second data object read from the object database is not a compressed byte array, by the computing device:
deserializing the second data object into a POCO entity;
serializing the POCO entity into a JSON object; and
sending the JSON object in a response to the request to read the second data object.

9. The method of claim 8, further comprising, prior to sending the JSON object, compressing the JSON object and sending the compressed JSON object in the response to the request to read the second data object.

10. A computing device comprising:
one or more non-transitory machine-readable mediums configured to store instructions; and
one or more processors configured to execute the instructions stored on the one or more non-transitory machine-readable mediums, wherein execution of the instructions causes the one or more processors to carry out a process comprising:
receiving a request to write a first data object to an object database; and
responsive to a determination that the first data object is a large data object:
serializing the first data object;
compressing the serialized first data object into a format that can be stored in the object database; and
saving the compressed serialized first data object within the object database.

11. The computing device of claim 10, wherein the serializing the first data object includes using a binary serializer to convert the first data object to a byte array.

12. The computing device of claim 10, wherein the compressing the serialized first data object includes using an LZ4 algorithm or a Zstandard (ZSTD) algorithm to compress the serialized first data object.

13. The computing device of claim 10, wherein the process further comprises, responsive to the determination that the first data object is a large data object:
extracting one or more fields which are queryable from the first data object; and
saving the one or more queryable fields with the compressed serialized first data object within the object database.

14. The computing device of claim 10, wherein the process further comprises, responsive to a determination that the first data object is not a large data object, saving the first data object within the object database.

15. The computing device of claim 10, wherein the process further comprises:
responsive to receiving a request to read a second data object from the object database, reading the second data object from the object database; and
responsive to a determination that the second data object read from the object database is a compressed byte array:
deserializing the second data object into a POCO entity which includes the compressed byte array, wherein the compressed byte array represents the second data object; and
sending the compressed byte array in a response to the request to read the second data object.

16. The computing device of claim 15, wherein the process further comprises, responsive to the determination that the second data object read from the object database is not a compressed byte array:
deserializing the second data object into a POCO entity;
serializing the POCO entity into a JSON object; and
sending the JSON object in a response to the request to read the second data object.

17. The computing device of claim 16, wherein the process further comprises, prior to sending the JSON object, compressing the JSON object and sending the compressed JSON object in the response to the request to read the second data object.

18. A non-transitory machine-readable medium encoding instructions that when executed by one or more processors cause a process to be carried out, the process including:
receiving a request to write a first data object to an object database; and
responsive to a determination that the first data object is a large data object:
serializing the first data object;
compressing the serialized first data object into a format that can be stored in the object database; and
saving the compressed serialized first data object within the object database.

19. The machine-readable medium of claim 18, wherein the process further comprises, responsive to the determination that the first data object is a large data object:
extracting one or more fields which are queryable from the first data object; and
saving the one or more queryable fields with the compressed serialized first data object within the object database.

20. The machine-readable medium of claim 18, wherein the process further comprises:
responsive to receiving a request to read a second data object from the object database, reading the second data object from the object database; and
responsive to a determination that the second data object read from the object database is a compressed byte array:
deserializing the second data object into a POCO entity which includes the compressed byte array, wherein the compressed byte array represents the second data object; and
sending the compressed byte array in a response to the request to read the second data object.
